(19) United States
(12) Patent Application Publication
(10) Pub. No.: US 2020/0104980 A1
(43) Pub. Date: Apr. 2, 2020

(54) MULTI-ELECTRON BEAM IMAGE ACQUISITION APPARATUS, AND MULTI-ELECTRON BEAM IMAGE ACQUISITION METHOD

(71) Applicant: NuFlare Technology, Inc., Yokohama-shi (JP)

(72) Inventors: Kazuhiko INOUE, Yokohama-shi (JP); Atsushi Ando, Edogawa-ku (JP)

(73) Assignee: NuFlare Technology, Inc., Yokohama-shi (JP)

(21) Appl. No.: 16/548,223

(22) Filed: Aug. 22, 2019

(30) Foreign Application Priority Data
Sep. 28, 2018 (JP) 2018-184857

(51) Int. Cl. G06T 5/00; H01J 37/20; H01J 37/28; G02B 7/09; G06T 3/60

(52) U.S. Cl. CPC G06T 5/003; H01J 37/20; H01J 37/28; G06T 2207/10061; G06T 3/60; G06T 2207/20172; G02B 7/09

(57) ABSTRACT

A multi-electron beam image acquisition apparatus includes a first electrostatic lens and a second electrostatic lens configured to, using one of a table and an approximate expression, dynamically correct the focus position deviation amount deviated from the reference position because of a change of a height position of a surface of a substrate changed along with movement of a stage, and correct one of a rotation change amount and a magnification change amount depending on a focus position deviation amount by interaction; and an image processing circuit configured to, using the one of the table and the approximate expression, correct another of the rotation change amount and the magnification change amount depending on the focus position deviation amount, with respect to a secondary electron image based on a detection signal of multiple secondary electron beams having been detected.

### CROSS-REFERENCE TO RELATED APPLICATION

This application is based upon and claims the benefit of priority from prior Japanese Patent Application No. 2018-184857 filed on Sep. 28, 2018 in Japan, the entire contents of which are incorporated herein by reference.

### BACKGROUND OF THE INVENTION

### Field of the Invention

Embodiments of the present invention relate to a multi-electron beam image acquisition apparatus and a multi-electron beam image acquisition method. For example, embodiments of the present invention relate to an apparatus that acquires a secondary electron image of a pattern emitted by irradiation with multiple electron beams.

### Description of Related Art

In recent years, with the advance of high integration and large capacity of LSI (Large Scale Integrated circuits), the line width (critical dimension) required for circuits of semiconductor elements is becoming increasingly narrower. Since LSI manufacturing requires a tremendous amount of manufacturing cost, it is crucially essential to improve its yield. However, as typified by a 1-gigabit DRAM (Dynamic Random Access Memory), the scale of patterns which configure the LSI now has become on the order of nanometers from submicrons. Also, in recent years, with miniaturization of LSI patterns formed on a semiconductor wafer, dimensions to be detected as a pattern defect have become extremely small. Therefore, the pattern inspection apparatus for inspecting defects of ultrafine patterns exposed/transferred onto a semiconductor wafer needs to be highly accurate. Further, one of major factors that decrease the yield of the LSI manufacturing is due to pattern defects on the mask used for exposing/transferring an ultrafine pattern onto a semiconductor wafer by the photolithography technology. Therefore, the pattern inspection apparatus for inspecting defects on a transfer mask used in manufacturing LSI needs to be highly accurate.

As an inspection method, there is known a method of comparing a measured image acquired by imaging a pattern formed on a substrate, such as a semiconductor wafer or a lithography mask, with design data or with another measured image acquired by imaging an identical pattern on the substrate. For example, as a pattern inspection method, there are “die-to-die inspection” and “die-to-database inspection”. The “die-to-die inspection” method compares data of measured images acquired by imaging identical patterns at different positions on the same substrate. The “die-to-database inspection” method generates, based on pattern design data, design image data (reference image) to be compared with a measured image being measured data acquired by imaging a pattern. Then, acquired images are transmitted as measured data to the comparison circuit. After alignment between images, the comparison circuit compares the measured data with the reference data according to an appropriate algorithm, and determines that there is a pattern defect if the compared data do not match with each other.

Specifically with respect to the pattern inspection apparatus described above, in addition to the type of apparatus that irradiates an inspection substrate with laser beams in order to obtain a transmission image or a reflection image of a pattern formed on the substrate, there has been developed another inspection apparatus that acquires a pattern image by scanning the inspection substrate with electron beams and detecting secondary electrons emitted from the inspection substrate by the irradiation with the electron beams. With the inspection apparatus utilizing an electron beam, an apparatus using multiple beams has also been under development. With respect to such an inspection apparatus using multiple beams, the surface height position of the inspection substrate changes due to unevenness such as thickness variation of the substrate. Accordingly, when irradiating the substrate with multiple beams while continuously moving the stage, it is necessary to continuously adjust the focus position of the multiple beams on the substrate surface in order to acquire an image with high resolution. Since it is difficult for an objective lens to correspond to the unevenness of the surface of the substrate on the stage continuously moving, it becomes necessary to dynamically correct the focus position by using an electrostatic lens with high responsivity. If the focus position is corrected using an electrostatic lens, magnification change and rotation change of an image occur along with the correction. Therefore, these three change factors need to be corrected simultaneously. It is theoretically possible to correct these three change factors, for example, by using three or more electrostatic lenses (refer to, e.g., Japanese Patent Application Laid-open (JP-A) No. 2014-127568). However, there occur problems that a space for installing the three or more electrostatic lenses is needed in the electron optical column, and that the control system becomes enlarged because the three or more electrostatic lenses need to be controlled simultaneously. Therefore, a structure is required which enables to make the installation space smaller and to perform control more easily compared to the conventional one. This problem is not limited to the inspection apparatus, and may similarly occur in the apparatus that acquires an image by focusing multiple beams on the substrate continuously moving.

### BRIEF SUMMARY OF THE INVENTION

According to one aspect of the present invention, a multi-electron beam image acquisition apparatus includes a stage which is configured to mount thereon a substrate to be irradiated with multiple electron beams, and is movable continuously; an objective lens configured to focus the multiple electron beams on a reference position on a surface of the substrate; a storage device configured to store one of a table and a parameter in an approximate expression, where a rotation change amount and a magnification change amount of an image of the multiple electron beams, generated due to correcting a focus position deviation amount deviated from the reference position because of change of a height position of the surface of the substrate, are defined depending on the focus position deviation amount; a first electrostatic lens and a second electrostatic lens configured to, using the one of the table and the approximate expression, dynamically correct the focus position deviation amount deviated from the reference position because of the change of the height position of the surface of the substrate changed along with movement of the stage, and correct one of the rotation change amount and the magnification change amount depending on the focus position deviation amount by interaction; a detector configured to detect multiple secondary electron beams emitted from the substrate by irradiation on the substrate with the multiple electron beams having been corrected by the first electrostatic lens and the second electrostatic lens; and an image processing circuit configured to, using the one of the table and the approximate expression, correct another of the rotation change amount and the magnification change amount depending on the focus position deviation amount, with respect to a secondary electron image based on a detection signal of the multiple secondary electron beams having been detected.

According to another aspect of the present invention, a multi-electron beam image acquisition apparatus includes a stage which is configured to mount thereon a substrate to be irradiated with multiple electron beams, and is movable continuously; an objective lens configured to focus the multiple electron beams on a reference position on a surface of the substrate; a first electrostatic lens configured to dynamically correct a focus position deviation amount, deviated from the reference position, generated along with movement of the stage; a storage device configured to store one of a table and a parameter in an approximate expression, where a rotation change amount and a magnification change amount of an image of the multiple electron beams, generated due to dynamically correcting the focus position deviation amount by the first electrostatic lens, are defined depending on the focus position deviation amount; a detector configured to detect multiple secondary electron beams emitted from the substrate by irradiation on the substrate with the multiple electron beams having been corrected by the first electrostatic lens; and an image processing circuit configured to, using the one of the table and the approximate expression, correct both of the rotation change amount and the magnification change amount depending on the focus position deviation amount, with respect to a secondary electron image based on a detection signal of the multiple secondary electron beams having been detected.

According to yet another aspect of the present invention, a multi-electron beam image acquisition method includes moving a stage with thereon a substrate in a state where multiple electron beams are focused on a reference position on a surface of the substrate by an objective lens; reading, from a storage device, one of a table and an approximate expression in which a rotation change amount and a magnification change amount of an image of the multiple electron beams, generated due to correcting a focus position deviation amount deviated from the reference position because of change of a height position of the surface of the substrate, are defined depending on the focus position deviation amount, and dynamically correcting, with a first electrostatic lens anda second electrostatic lens, the focus position deviation amount deviated from the reference position because of the change of the height position of the surface of the substrate changed along with movement of the stage, and one of the rotation change amount and the magnification change amount depending on the focus position deviation amount by interaction, using the one of the table and the approximate expression; detecting multiple secondary electron beams emitted from the substrate by irradiation on the substrate with the multiple electron beams having been corrected by the first electrostatic lens and the second electrostatic lens; and correcting, using the one of the table and the approximate expression, another of the rotation change amount and the magnification change amount depending on the focus position deviation amount, with respect to a secondary electron image based on a detection signal of the multiple secondary electron beams having been detected, and outputting a corrected secondary electron image.

According to yet another aspect of the present invention, a multi-electron beam image acquisition method includes moving a stage with thereon a substrate in a state where multiple electron beams are focused on a reference position on a surface of the substrate by an objective lens; correcting dynamically, by a first electrostatic lens, a focus position deviation amount deviated from the reference position on the surface of the substrate and generated along with movement of the stage; detecting multiple secondary electron beams emitted from the substrate by irradiation on the substrate with the multiple electron beams having been corrected by the first electrostatic lens; and reading, from a storage device which stores one of a table and a parameter in an approximate expression, the one of the table and the approximate expression in which a rotation change amount and a magnification change amount of an image of the multiple electron beams, generated due to dynamically correcting the focus position deviation amount by the first electrostatic lens, are defined depending on the focus position deviation amount, and correcting, using the one of the table and the approximate expression, both of the rotation change amount and the magnification change amount depending on the focus position deviation amount, with respect to a secondary electron image based on a detection signal of the multiple secondary electron beams having been detected, so as to output a corrected secondary electron image.

### BRIEF DESCRIPTION OF THE DRAWINGS

FIG. 1 shows a configuration of a pattern inspection apparatus according to a first embodiment;

FIG. 2 is a conceptual diagram showing a configuration of a shaping aperture array substrate according to the first embodiment;

FIG. 3A shows an example of arrangement structure of an electromagnetic lens and an electrostatic lens according to the first embodiment;

FIG. 3B shows a central beam trajectory according to the first embodiment;

FIG. 4 is a flowchart showing main steps of an inspection method according to the first embodiment;

FIG. 5 shows an example of a correlation table according to the first embodiment;

FIG. 6 shows a relation of an electrostatic lens arrangement position, a focus position deviation amount, an image magnification change amount, and an image rotation change amount according to the first embodiment;

FIG. 7 shows an example of a plurality of chip regions formed on a semiconductor substrate, according to the first embodiment;

FIG. 8 illustrates a scanning operation with multiple beams according to the first embodiment;

FIG. 9 illustrates an image correction method according to the first embodiment;

FIG. 10 shows an example of an internal configuration of a comparison circuit according to the first embodiment;

FIG. 11 shows a configuration of a pattern inspection apparatus according to the second embodiment; and

FIG. 12 is a flowchart showing main steps of an inspection method according to the second embodiment.

### DETAILED DESCRIPTION OF THE INVENTION

Embodiments below describe an apparatus and method that can make the installation space smaller and perform control more easily compared to the conventional one in an apparatus that acquires an image by focusing multiple beams on the substrate continuously moving.

Embodiments below describe a multiple electron beam inspection apparatus as an example of a multiple electron beam irradiation apparatus. The multiple electron beam irradiation apparatus is not limited to the inspection apparatus, and may be, for example, any apparatus that irradiates multiple electron beams through an electron optical system.

### First Embodiment

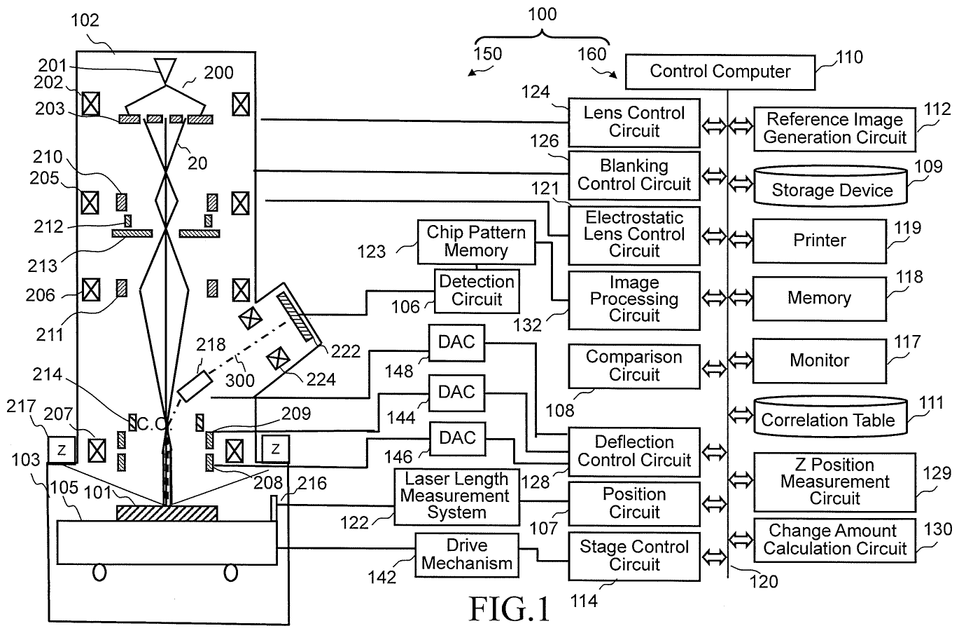

FIG. 1 shows a configuration of a pattern inspection apparatus according to a first embodiment. In FIG. 1, an inspection apparatus 100 for inspecting patterns formed on a substrate is an example of a multiple electron beam inspection apparatus. The inspection apparatus 100 includes an image acquisition mechanism 150 and a control system circuit 160. The image acquisition mechanism 150 includes an electron beam column 102 (electron optical column) and an inspection chamber 103. In the electron beam column 102, there are disposed an electron gun 201, an electromagnetic lens 202, a shaping aperture array substrate 203, an electromagnetic lens 205, an electrostatic lens 210, a common blanking deflector 212, a limiting aperture substrate 213, an electromagnetic lens 206, an electrostatic lens 211, an electromagnetic lens 207 (objective lens), a main deflector 208, a sub deflector 209, a beam separator 214, a deflector 218, an electromagnetic lens 224, and a multi-detector 222.

A stage 105 movable at least in the x, y, and z directions is disposed in the inspection chamber 103. A substrate 101 (target object) to be inspected is mounted on the stage 105. The substrate 101 may be an exposure mask substrate, or a semiconductor substrate such as a silicon wafer. When the substrate 101 is a semiconductor substrate, a plurality of chip patterns (wafer dies) are formed on the semiconductor substrate. When the substrate 101 is an exposure mask substrate, a chip pattern is formed on the exposure mask substrate. The chip pattern is composed of a plurality of figure patterns. If the chip pattern formed on the exposure mask substrate is exposed/transferred onto the semiconductor substrate a plurality of times, a plurality of chip patterns (wafer dies) are formed on the semiconductor substrate. The case of the substrate 101 being a semiconductor substrate is described below mainly. The substrate 101 is placed with its pattern-forming surface facing upward on the stage 105, for example. Moreover, on the stage 105, there is disposed a mirror 216 which reflects a laser beam for measuring a laser length emitted from the laser length measuring system 122 disposed outside the inspection chamber 103. In the inspection chamber 103, a height position sensor (Z sensor) 217 which measures the height position of the surface of the substrate 101 is disposed. The projector of the Z sensor 217 irradiates the surface of the substrate 101 with a laser beam from obliquely upward, and the photodetector (photoreceiver) of the Z sensor 217 receives a reflected light of the laser beam in order to measure the height position of the surface of the substrate 101. The multi-detector 222 is connected, at the outside of the electron beam column 102, to the detection circuit 106. The detection circuit 106 is connected to the chip pattern memory 123.

In the control system circuit 160, a control computer 110 which controls the whole of the inspection apparatus 100 is connected, through a bus 120, to a position circuit 107, a comparison circuit 108, a reference image generation circuit 112, a stage control circuit 114, an electrostatic lens control circuit 121, a lens control circuit 124, a blanking control circuit 126, a deflection control circuit 128, a Z position measurement circuit 129, a change amount calculation circuit 130, an image processing circuit 132, storage devices 109 and 111, such as a magnetic disk drive, a monitor 117, a memory 118, and a printer 119. The deflection control circuit 128 is connected to DAC (digital-to-analog conversion) amplifiers 144, 146 and 148. The DAC amplifier 146 is connected to the main deflector 208, and the DAC amplifier 144 is connected to the sub deflector 209. The DAC amplifier 148 is connected to the deflector 218.

The chip pattern memory 123 is connected to the image processing circuit 132. The stage 105 is driven by the drive mechanism 142 under the control of the stage control circuit 114. With respect to the drive mechanism 142, the drive system, such as a three (x-, y-, and θ-) axis motor which provides drive in the directions of x, y, and θ in the stage coordinate system, can move the stage 105 in the x, y, and θ directions. A step motor, for example, can be used as each of these x, y, and θ motors (not shown). The stage 105 is movable in the horizontal direction and the rotation direction by the motors of the x-axis, y-axis, and θ-axis. In addition, the stage 105 is movable in the z direction (height direction) by using a piezoelectric element, etc., for example. The movement position of the stage 105 is measured by the laser length measuring system 122, and supplied (transmitted) to the position circuit 107. Based on the principle of laser interferometry, the laser length measuring system 122 measures the position of the stage 105 by receiving a reflected light from the mirror 216. In the stage coordinate system, the x, y, and 0 directions are set with respect to a plane orthogonal to the optical axis of the multiple primary electron beams, for example.

The electromagnetic lenses 202, 205, 206, 207 (objective lens), 224 and the beam separator 214 are controlled by the lens control circuit 124. The common blanking deflector 212 is configured by two or more electrodes (or “two or more poles”), and each electrode is controlled by the blanking control circuit 126 through a DAC amplifier (not shown). The electrostatic lenses 210 and 211, each of which is configured by, for example, electrode substrates arranged in three or more stages each having an opening in the center, and the middle electrode substrate is controlled by the electrostatic lens control circuit 121 through a DAC amplifier (not shown). Ground potentials are applied to the upper and lower electrode substrates of the electrostatic lens 210 and 211. The sub deflector 209 is configured by four or more electrodes (or “four or more poles”), and each electrode is controlled by the deflection control circuit 128 through the DAC amplifier 144. The main deflector 208 is configured by four or more electrodes (or “four or more poles”), and each electrode is controlled by the deflection control circuit 128 through the DAC amplifier 146. The deflector 218 is configured by four or more electrodes (or “four or more poles”), and each electrode is controlled by the deflection control circuit 128 through the DAC amplifier 148.

To the electron gun 201, there is connected a high voltage power supply circuit (not shown). The high voltage power supply circuit applies an acceleration voltage between a filament (cathode) and an extraction electrode (anode) (which are not shown) in the electron gun 201. In addition to applying the acceleration voltage as described above, applying a voltage to another extraction electrode (Wehnelt) and heating the cathode to a predetermined temperature are performed, and thereby, electrons from the cathode are accelerated to be emitted as electron beams 200.

FIG. 1 shows configuration elements necessary for describing the first embodiment. It should be understood that other configuration elements generally necessary for the inspection apparatus 100 may also be included therein.

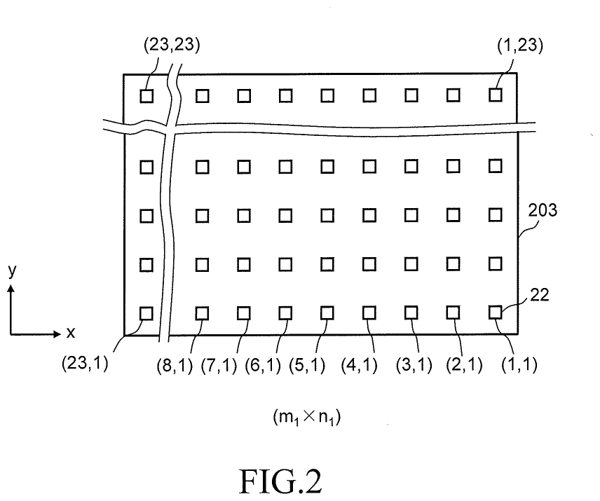

FIG. 2 is a conceptual diagram showing a configuration of a shaping aperture array substrate according to the first embodiment. As shown in FIG. 2, holes (openings) 22 of m₁ columns wide (width in the x direction) and n₁ rows long (length in the y direction) are two-dimensionally formed at a predetermined arrangement pitch in the shaping aperture array substrate 203, where m₁ and n₁ are integers of 2 or more. In the case of FIG. 2, holes 22 of 23 (columns of holes arrayed in the x direction)×23 (rows of holes arrayed in the y direction) are formed. Each of the holes 22 is a rectangle (including a square) having the same dimension, shape, and size. Alternatively, each of the holes 22 may be a circle with the same outer diameter. Multiple beams 20 are formed by letting portions of the electron beam 200 individually pass through a corresponding one of a plurality of holes 22. With respect to the arrangement of the holes 22, although the case where the holes 22 of two or more rows and columns are arranged in both the x and y directions is here shown, the arrangement is not limited thereto. For example, it is also acceptable that a plurality of holes 22 are arranged in only one row (in the x direction) or in only one column (in the y direction). That is, in the case of only one row, a plurality of holes 22 are arranged in the x direction as a plurality of columns, and in the case of only one column, a plurality of holes 22 are arranged in the y direction as a plurality of rows. The method of arranging the holes 22 is not limited to the case of FIG. 2 where holes are arranged in a grid form in the width and length directions. For example, with respect to the kth and the (k+1)th rows, where the two rows are arrayed (accumulated) in the length direction (in the y direction) and each of the rows is in the x direction, each hole in the kth row and each hole in the (k+1)th row may be mutually displaced in the width direction (in the x direction) by a dimension “a”. Similarly, with respect to the (k+1)th and the (k+2)th rows, where the two rows are arrayed (accumulated) in the length direction (in the y direction) and each of the rows is in the x direction, each hole in the (k+1)th row and each hole in the (k+2)th row may be mutually displaced in the width direction (in the x direction) by a dimension “b”.

Next, operations of the image acquisition mechanism 150 in the inspection apparatus 100 will be described below.

The electron beam 200 emitted from the electron gun 201 (emission source) is refracted by the electromagnetic lens 202, and illuminates the whole of the shaping aperture array substrate 203. As shown in FIG. 2, a plurality of holes 22 (openings) are formed in the shaping aperture array substrate 203. The region including all the plurality of holes 22 is irradiated by the electron beam 200. The multiple beams 20 (multiple primary electron beams) are formed by letting portions of the electron beam 200, which irradiate the positions of a plurality of holes 22, individually pass through a corresponding one of the plurality of holes 22 in the shaping aperture array substrate 203.

The formed multiple beams 20 are individually refracted by the electromagnetic lenses 205 and 206, and travel to the electromagnetic lens 207 (objective lens) while repeating forming an intermediate image and a crossover through the beam separator 214 disposed at the crossover position of each beam of the multiple beams 20. Then, the electromagnetic lens 207 focuses the multiple beams 20 onto the substrate 101. The multiple beams 20 having been focused on the substrate 101 (target object) by the objective lens 207 are collectively deflected by the main deflector 208 and the sub deflector 209 to irradiate respective beam irradiation positions on the substrate 101. When all of the multiple beams 20 are collectively deflected by the common blanking deflector 212, they deviate from the hole in the center of the limiting aperture substrate 213 and blocked by the limiting aperture substrate 213. On the other hand, the multiple beams 20 which were not deflected by the common blanking deflector 212 pass through the hole in the center of the limiting aperture substrate 213 as shown in FIG. 1. Blanking control is provided by ON/OFF of the common blanking deflector 212 to collectively control ON/OFF of the multiple beams. Thus, the limiting aperture substrate 213 blocks the multiple beams 20 which were deflected to be in the OFF condition by the common blanking deflector 212. Then, the multiple beams 20 for inspection (for image acquisition) are formed by the beams having been made during a period from becoming “beam ON” to becoming “beam OFF” and having passed through the limiting aperture substrate 213.

When desired positions on the substrate 101 are irradiated with the multiple beams 20, a flux of secondary electrons (multiple secondary electron beams 300) including reflected electrons each corresponding to each of the multiple beams 20 (multiple primary electron beams) is emitted from the substrate 101 due to the irradiation by the multiple beams 20.

The multiple secondary electron beams 300 emitted from the substrate 101 travel to the beam separator 214 through the electromagnetic lens 207.

The beam separator 214 generates an electric field and a magnetic field to be orthogonal to each other in a plane perpendicular to the traveling direction (trajectory central axis) of the center beam of the multiple beams 20. The electric field affects (exerts a force) in the same fixed direction regardless of the traveling direction of electrons. In contrast, the magnetic field affects (exerts a force) according to Fleming's left-hand rule. Therefore, the direction of force acting on (applied to) electrons can be changed depending on the traveling (or “entering”) direction of the electrons. With respect to the multiple beams 20 entering the beam separator 214 from the upper side, since the force due to the electric field and the force due to the magnetic field cancel each other out, the multiple beams 20 travel straight downward. In contrast, with respect to the multiple secondary electron beams 300 entering the beam separator 214 from the lower side, since both the force due to the electric field and the force due to the magnetic field are exerted in the same direction, the multiple secondary electron beams 300 are bent obliquely upward, and separated from the multiple beams 20.

The multiple secondary electron beams 300 bent obliquely upward and separated from the multiple beams 20 are further bent by the deflector 218, and projected, while being refracted, onto the multi-detector 222 by the electromagnetic lens 224. FIG. 1 shows a simplified trajectory of the multiple secondary electron beams 300 without refraction. The multi-detector 222 detects the projected multiple secondary electron beams 300. The multi-detector 222 includes, for example, a diode type two-dimensional sensor (not shown). Then, at a diode type two-dimensional sensor position corresponding to each beam of the multiple beams 20, each secondary electron of the multiple secondary electron beams 300 collides with the diode type two-dimensional sensor to generate an electron, and produces secondary electron image data for each pixel. An intensity signal detected by the multi-detector 222 is output to the detection circuit 106.

The height position of the surface of the substrate 101 serving as an inspection target changes because unevenness exists on the surface of the substrate 101 due to thickness variation of the substrate. When the height position of the surface of the substrate 101 changes, the focus position deviates. Therefore, the size of each beam applied to the substrate 101 changes. If the beam size changes, the number of secondary electrons emitted from the irradiation position also changes. Thus, an error occurs in detected intensity, and therefore, an acquired image becomes changed from the one having no detected intensity error. Therefore, when irradiating the substrate 101 with the multiple beams 20 while continuously moving the stage 105, it is necessary to continuously adjust the focus position of the multiple beams 20 on the substrate 101 in order to acquire an image with high resolution. Since it is difficult for the electromagnetic lens 207 (objective lens) to correspond to the unevenness of the surface of the substrate 101 on the stage 105 continuously moving, it becomes necessary to dynamically correct the focus position by using the electrostatic lens 210 with high responsivity.

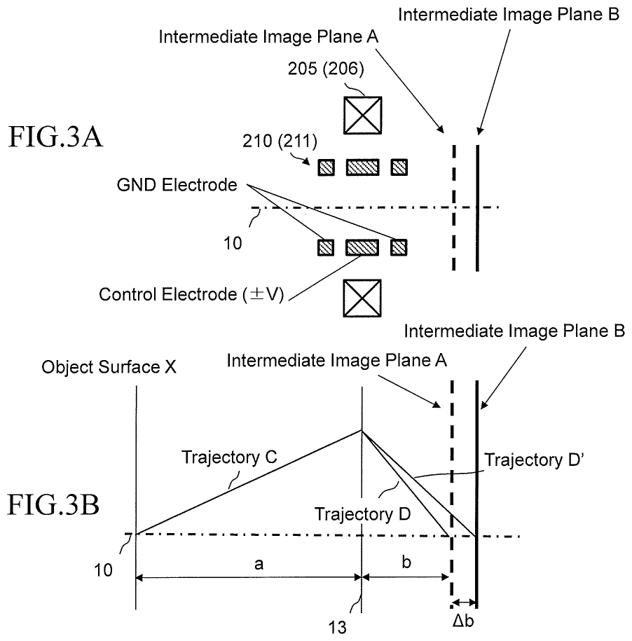

FIG. 3A shows an example of arrangement structure of an electromagnetic lens and an electrostatic lens according to the first embodiment. FIG. 3B shows a central beam trajectory according to the first embodiment. In FIG. 3A, the electrostatic lens 210 is configured by electrode substrates arranged in three stages. The middle electrode substrate serving as a control electrode is disposed at the magnetic field center position of the electromagnetic lens 205. Ground potentials are applied to the upper and lower electrode substrates. Lens adjustment is implemented such that each of the electromagnetic lenses 205, 206, and 207 is focused on the surface of the substrate 101. In such a state, in FIG. 3B, the center beam of the multiple beams 20 enters the electromagnetic lens 205 while gradually spreading against the trajectory central axis 10 of the multiple beams 20 as shown by the trajectory C. Then, the center beam is refracted at the principal surface 13 of the electromagnetic lens 205, converged as shown by the trajectory D, and focused onto the intermediate image plane A (position conjugate to the image plane). Here, if the surface of the substrate 101 changes, an electrostatic field is generated by the electrostatic lens 210 and the focusing action is changed in accordance with change of the height position of the surface of the substrate 101 so that the center beam may be converged along the trajectory D′ and focused onto the intermediate image plane B (position conjugate to the image plane). Through this focusing action, the magnification M of the multiple beams 20 is changed from b/a to (b+Δb)/a. Thus, it turns out that magnification of an image changes depending on change of an imaging surface (focus position). Moreover, rotation change of the multiple beams occurs simultaneously. The principal surface 13 of the lens indicates here a plane at the position of the intersection between the trajectory C of an electron emitted to the principal surface 13 of the lens from the object surface X, and the trajectory D of an electron going to the intermediate image plane A (or the trajectory D′ of an electron going to the intermediate image plane B) from the principal surface 13 of the lens. The same can be said for the relation between the electrostatic lens 211 and the electromagnetic lens 206.

As described above, if focus position change (focus position deviation amount ΔZ1) is corrected, magnification change (magnification change amount ΔM1) and rotation change (rotation change amount Δθ1) of an image occur along with the correction. Therefore, these three change factors need to be corrected simultaneously. It is theoretically possible to correct these three change factors, for example, by three or more electrostatic lenses. However, as described above, there occur problems that a space for installing the three or more electrostatic lenses is needed in the electron optical column, and that the control system becomes enlarged because the three or more electrostatic lenses need to be controlled simultaneously. Therefore, a structure is required which enables to make the installation space smaller and to perform control more easily compared to the conventional one. Then, with respect to the three change factors, namely a focus position deviation amount ΔZ1 on the substrate 101, a magnification change amount ΔM1 and a rotation change amount Δθ1 of an image, according to the first embodiment, the focus position deviation amount ΔZ1 and one of the magnification change amount ΔM1 and the rotation change amount Δθ1 of the image are corrected by the two electrostatic lenses 210 and 211, and the other one of the two is corrected by image processing.

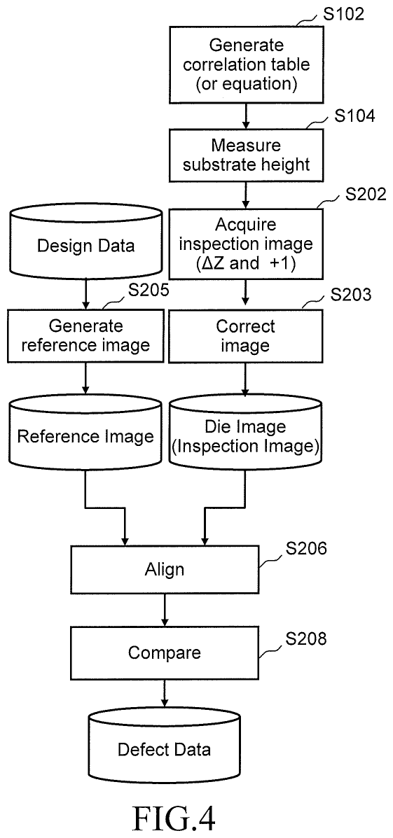

FIG. 4 is a flowchart showing main steps of an inspection method according to the first embodiment. In FIG. 4, the inspection method of the first embodiment executes a series of steps: a correlation table (or correlation equation) generating step (S102), a substrate height measuring step (S104), an inspection image acquiring step (S202), an image correcting step (S203), a reference image generating step (S205), an aligning (positioning) step (S206), and a comparing step (S208).

In the correlation table (or correlation equation) generating step (S102), the multiple beams 20 are focused on a sample substrate on the stage 105 by the electromagnetic lens 207 (objective lens), where the height position of the sample substrate has been adjusted to the reference height position. Then, in this state, the stage 105 is variably moved in the Z direction. Each height position is measured by the Z sensor 217. The moved amount of each height position is a focus position deviation amount ΔZ1 of the multiple beams 20. For example, the focus position deviation amount ΔZ1 of the multiple beams 20 on the surface of the substrate 101, which is generated due to moving the stage 105 to each height position, is corrected using the electrostatic lens 210. Then, with respect to the deviation amount ΔZ1 of each focus position, are measured a rotation change amount Δθ1 and a magnification change amount ΔM1 of an image of the multiple beams 20 on the surface of the substrate 101, which are generated due to correcting the deviation amount of each focus position. Next, a correlation table is generated where are defined the rotation change amount Δθ1 and magnification change amount ΔM1 of an image which are depending on the focus position deviation amount ΔZ1.

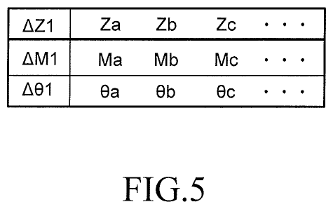

FIG. 5 shows an example of a correlation table according to the first embodiment. In FIG. 5, the correlation table defines the image rotation change amount Δθ1 and the image magnification change amount ΔM1 generated in the case of correcting the deviation amount ΔZ1 of each focus position by, for example, the electrostatic lens 210 when the deviation amount ΔZ1 of the focus position on the substrate 101 changes such as Za, Zb, Zc, and so on. FIG. 5 shows the case where when the deviation amount ΔZ1 of the focus position on the substrate 101 is Za, the image magnification change amount ΔM1 and the image rotation change amount ΔZ1 on the substrate 101, generated if the deviation amount Za is corrected by the electrostatic lens 210, for example, are Ma(=ΔM1) and θa (=Δθ1). Similarly, when the deviation amount ΔZ1 of the focus position on the substrate 101 is Zb, the image magnification change amount ΔM1 and the image rotation change amount Δθ1 on the substrate 101, generated if the deviation amount Zb is corrected by the electrostatic lens 210, for example, are Mb(=ΔM1) and θb(=Δθ1). Similarly, when the deviation amount ΔZ1 of the focus position on the substrate 101 is Zc, the image magnification change amount ΔM1 and the image rotation change amount Δθ1 on the substrate 101, generated if the deviation amount Zc is corrected by the electrostatic lens 210, for example, are Mc(=ΔM1) and θc(=Δθ1).

Alternatively, a correlation equation may be used instead of a correlation table. For example, ΔM1 is approximated by ΔM1=k·ΔZ1, and Δθ1 is approximated by Δθ1=k′·ΔZ1. Coefficients (parameters) k and k′ of the approximate expression are previously calculated. Although here a primary (linear) expression is used as an example, it is not limited thereto. Approximation may also be performed using a polynomial including a second or higher order term.

The generated correlation table or calculated parameters k and k′ are stored in the storage device ill.

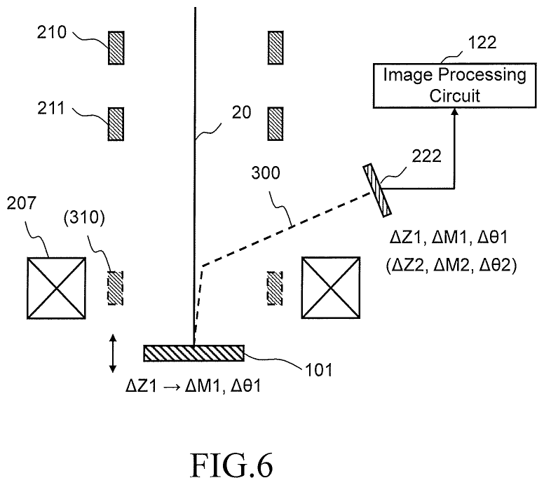

FIG. 6 shows a relation of an electrostatic lens arrangement position, a focus position deviation amount, an image magnification change amount, and an image rotation change amount according to the first embodiment. In FIG. 6, if, just as an example, disposing the electrostatic lens 310 in the magnetic field of the electromagnetic lens 207 (objective lens) and correcting a deviation amount of the focus position of the multiple beams 20 (multiple primary electron beams) by the electrostatic lens 310, a magnification change amount ΔM1 and a rotation change amount Δθ1 of an image are generated on the surface of the substrate 101 due to that the focus position deviation amount ΔZ1 has been corrected. Then, the multiple secondary electron beams 300 emitted from the substrate 101 by irradiation with the multiple beams 20 pass through the electrostatic lens 310. Thereby, a new change is generated in the multiple secondary electron beams 300 by the electrostatic field of the electrostatic lens 310. Therefore, the multi-detector 222 detects the multiple secondary electron beams 300 in which the focus position deviation amount ΔZ2, the image magnification change amount ΔM2, and the image rotation change amount Δ82, where the new change is included, have been generated. Thus, the change amounts vary complicatedly. In contrast, according to the first embodiment, the electrostatic lens 210 (first electrostatic lens) and the electrostatic lens 211 (second electrostatic lens) are disposed at the positions through which the multiple secondary electron beams 300 do not pass. In other words, the electrostatic lens 210 and the electrostatic lens 211 are disposed upstream of the beam separator 214 with respect to an advancing direction of the multiple beams 20. In the first embodiment, similarly to the example described above, when correcting the deviation amount of the focus position of the multiple beams 20 (multiple primary electron beams) by the electrostatic lens 210 (or electrostatic lens 211), the magnification change amount ΔM1 and the rotation change amount Δθ1 of an image are generated on the substrate 101 due to that the focus position deviation amount ΔZ1 has been corrected. However, since the multiple secondary electron beams 300 is not affected by the electrostatic field, no new change occurs. Therefore, the multi-detector 222 detects the multiple secondary electron beams 300 in which the focus position deviation amount ΔZ2, the image magnification change amount ΔM2, and the image rotation change amount Δ82 have been generated. Thus, it is possible not to make the change amount (s) complicated. Therefore, image processing, to be described later, can be performed using the correlation table that defines the focus position deviation amount ΔZ1, the image magnification change amount ΔM1, and the image rotation change amount Δθ1 on the substrate 101.

In the substrate height measuring step (S104), the Z sensor 217 measures the height position of the substrate 101 to be inspected. The Z sensor 217 outputs a measurement result to the Z position measurement circuit 129. Moreover, information on each height position on the surface of the substrate 101 is stored in the storage device 109 together with the x and y coordinates of the measurement position on the surface of the substrate 101 measured by the position circuit 107. It is not limited to previously measuring the height position of the substrate 101 before acquiring an image. The height position of the substrate 101 may be measured in real time while acquiring an image.

In the inspection image acquiring step (S202), using the multiple beams 20, the image acquisition mechanism 150 acquires a secondary electron image of a pattern formed on the substrate 101. Specifically, it operates as follows:

First, the stage 105 with the substrate 101 thereon is moved in the state where the multiple beams 20 are focused on the reference position on the surface of the substrate 101 by the electromagnetic lens 207 (objective lens).

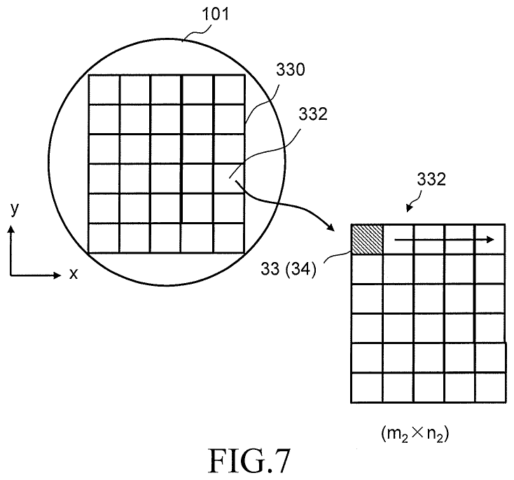

FIG. 7 shows an example of a plurality of chip regions formed on a semiconductor substrate, according to the first embodiment. In FIG. 7, in the case of the substrate 101 being a semiconductor substrate (wafer), a plurality of chips (wafer dies) 332 in a two-dimensional array are formed in an inspection region 330 of the semiconductor substrate (wafer die). A mask pattern for one chip formed on an exposure mask substrate is reduced to ¼, for example, and exposed/transferred onto each chip 332 by an exposure device (stepper) (not shown). The inside of each chip 332 is divided into a plurality of mask dies 33 two-dimensionally arrayed in m₂ columns wide (width in the x direction) and n₂ rows long (length in the y direction) (each of m₂ and n₂ is an integer of 2 or more), for example. In the first embodiment, the mask die 33 serves as a unit inspection region. Beam application to the mask die 33 concerned is achieved by collectively deflecting all the multiple beams 20 by the main deflector 208.

Prior to irradiating the mask die 33 concerned with the multiple beams 20, the change amount calculation circuit 130 reads the height position of the substrate 101 stored in the storage device 109, using the x and y coordinates of the irradiation positions of the multiple beams 20. The change amount calculation circuit 130 calculates a difference between the read height position and the reference position on the surface of the substrate 101 focused by the electromagnetic lens 207 (objective lens). This difference is equivalent to the focus position deviation amount ΔZ1 deviated from the reference position. Alternatively, it is also preferable to store in the storage device 109 information on the height position of the substrate 101 as a difference from the reference position, i.e., as the deviation amount ΔZ1 of the focus position deviated from the reference position.

Next, the change amount calculation circuit 130 reads the correlation table (or parameters k and k′ in the approximate expression) stored in the storage device 111, and, based on this correlation table (or approximate expression), calculates the rotation change amount Δθ1 and the magnification change amount ΔM1 depending on the focus position deviation amount ΔZ1 which is deviated from the reference position because of change of the height position of the surface of the substrate 101 changed along with movement of the stage 105. Each information on the focus position deviation amount ΔZ1, and one of the calculated rotation change amount Δθ1 and magnification change amount ΔM1 (for example, the rotation change amount Δθ1) are output to the electrostatic lens control circuit 121. Information on the other one of the calculated rotation change amount Δθ1 and magnification change amount ΔM1 (for example, the magnification change amount ΔM1) is output to the image processing circuit 132. Preferably, the focus position deviation amount ΔZ1, and the rotation change amount Δθ1 and the magnification change amount ΔM1, which are depending on the focus position deviation amount ΔZ1, are calculated for each mask die 33 used as a unit inspecting region. Alternatively, it is preferable to perform calculation for each movement length (distance) of the stage 105 shorter than the size of the mask die 33. Alternatively, it is also preferable to perform calculation for each movement length (distance) of the stage 105 longer than the size of the mask die 33.

The electrostatic lens control circuit 121 calculates a combination of a lens control value 1 of the electrostatic lens 210 and a lens control value 2 of the electrostatic lens 211 for correcting the focus position deviation amount ΔZ1, and one of the rotation change amount Δθ1 and the magnification change amount ΔM1 (for example, the rotation change amount Δθ1). Then, the electrostatic lens control circuit 121 applies an electric potential equivalent to the calculated lens control value 1 to the control electrode (middle electrode substrate) of the electrostatic lens 210, and applies an electric potential equivalent to the calculated lens control value 2 to the control electrode (middle electrode substrate) of the electrostatic lens 211. Since only two of the three change factors, namely the focus position deviation amount ΔZ1, the rotation change amount Δθ1, and the magnification change amount ΔM1, are corrected, it is easier to perform controlling than performing correction controlling of all the three change factors. Therefore, enlargement of the control system can be inhibited. Thus, as long as the height position of the substrate 101, further the amount deviation ΔZ1 of the focus position, can be acquired using the correlation table (or approximate expression), the rotation change amount Δθ1 and the magnification change amount ΔM1 can be obtained, thereby simplifying the control system.

The image acquisition mechanism 150 irradiates the substrate 101 with the multiple beams 20 while continuously moving the stage 105. By this, the electrostatic lens 210 (first electrostatic lens) and the electrostatic lens 211 (second electrostatic lens) dynamically correct, using the correlation table (or approximate expression), the focus position deviation amount ΔZ1 which is deviated from the reference position of the multiple beams 20 because of change of the height position of the surface of the substrate 101 changed along with movement of the stage 105, and one of the rotation change amount Δθ1 and the magnification change amount ΔM1 (for example, the rotation change amount Δ1) of an image of the multiple beams 20 on the substrate 101 which are depending on the focus position deviation amount ΔZ1 by interaction.

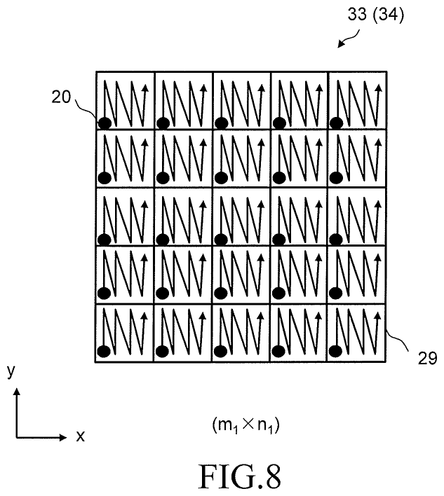

FIG. 8 illustrates a scanning operation with multiple beams according to the first embodiment. FIG. 8 shows the case of the multiple beams 20 of 5×5 (rows by columns). The size of an irradiation region 34 that can be irradiated by one irradiation with the multiple beams 20 is defined by (x direction size obtained by multiplying pitch between beams in the x direction of the multiple beams 20 on the substrate 101 by the number of beams in the x direction)×(y direction size obtained by multiplying pitch between beams in the y direction of the multiple beams 20 on the substrate 101 by the number of beams in the y direction). In the case of FIG. 8, the irradiation region 34 and the mask die 33 are of the same size. However, it is not limited thereto. The irradiation region 34 may be smaller than the mask die 33, or larger than it. Each beam of the multiple beams 20 scans the inside of a sub-irradiation region 29 surrounded by the pitch between beams in the x direction and the pitch between beams in the y direction, where the beam concerned itself is located. Each beam of the multiple beams 20 is associated with any one of the sub-irradiation regions 29 which are different from each other. At the time of each shot, each beam irradiates the same position in the associated sub-irradiation region 29. Movement of the beam in the sub-irradiation region 29 is executed by collective deflection of the whole multiple beams 20 by the sub deflector 209. By repeating this operation, one beam irradiates all the pixels in order in one sub-irradiation region 29. In addition, since the other one of the rotation change amount Δθ1 and the magnification change amount ΔM1 (for example, the magnification change amount ΔM1) remains in the data to be obtained, it is preferable to add a margin to the sub-irradiation region 29 to be scanned with each beam.

The multiple secondary electron beams 300 including reflected electrons, each corresponding to each of the multiple beams 20, are emitted from the substrate 101 because desired positions on the substrate 101 are irradiated with the multiple beams 20 having been corrected by the electrostatic lenses 210 and 211. The multiple secondary electron beams 300 emitted from the substrate 101 travel to the beam separator 214, and are bent obliquely upward. Then, the trajectory of the multiple secondary electron beams 300 having been bent obliquely upward is bent by the deflector 218, and projected on the multi-detector 222. As described above, the multi-detector 222 detects the multiple secondary electron beams 300, including reflected electrons, emitted because the substrate 101 surface is irradiated with the multiple beams 20.

Thus, the whole of the multiple beams 20 scans the mask die 33 as the irradiation region 34, and that is, each beam individually scans one corresponding sub-irradiation region 29. After scanning one mask die 33, the irradiation region 34 is moved to a next adjacent mask die 33 so as to be scanned. In conjunction with this operation, the electrostatic lenses 210 and 211 dynamically correct the focus position deviation amount ΔZ1 which is deviated from the reference position of the multiple beams 20, and one of the rotation change amount D01 and the magnification change amount ΔM1 (for example, the rotation change amount Ol) of an image of the multiple beams 20 on the substrate 101 which are depending on the focus position deviation amount ΔZ1. This operation is repeated to proceed scanning of each chip 332. Due to shots of the multiple beams 20, secondary electrons are emitted from the irradiated positions at each shot time, and detected by the multi-detector 222.

By performing scanning with the multiple beams 20 as described above, the scanning operation (measurement) can be performed at a higher speed than scanning with a single beam. When the irradiation region 34 is smaller than the mask die 33, the scanning operation can be performed while moving the irradiation region 34 in the mask die 33 concerned.

In the case of the substrate 101 being an exposure mask substrate, the chip region for one chip formed on the exposure mask substrate is divided into a plurality of stripe regions in a strip form by the size of the mask die 33 described above, for example. Then, each mask die 33 is scanned through the same scanning operation described above for each stripe region. Since the size of the mask die 33 on the exposure mask substrate is the size before being transferred and exposed, it is four times the mask die 33 on the semiconductor substrate. Therefore, if the irradiation region 34 is smaller than the mask die 33 on the exposure mask substrate, the operation for scanning one chip increases (e.g., four times). However, since a pattern for one chip is formed on the exposure mask substrate, the number of times of scanning can be less compared to the case of the semiconductor substrate on which more than four chips are formed.

As described above, using the multiple beams 20, the image acquisition mechanism 150 scans the substrate 101 to be inspected on which a figure pattern is formed, and detects the multiple secondary electron beams 300 emitted from the inspection substrate 101 by irradiation with the multiple beams 20 onto the inspection substrate 101. Detected data (measured image: secondary electron image: image to be inspected) on a secondary electron from each measurement pixel 36 detected by the multi-detector 222 is output to the detection circuit 106 in order of measurement. In the detection circuit 106, the detected data in analog form is converted into digital data by an A-D converter (not shown), and stored in the chip pattern memory 123. Thus, the image acquisition mechanism 150 acquires a measured image of a pattern formed on the substrate 101. Then, for example, when the detected data for one chip 332 has been accumulated, the accumulated data is transmitted as chip pattern data to the image processing circuit 132, together with information data on each position from the position circuit 107.

In the image correcting step (S203), using the correlation table (or approximate expression), the image processing circuit 132 (image processing unit) corrects the other one of the rotation change amount Δθ1 and the magnification change amount ΔM1 (for example, the magnification change amount ΔM1) which are depending on the deviation amount ΔZ1 of the focus position, with respect to a secondary electron image based on a detection signal of detected multiple secondary electron beams.

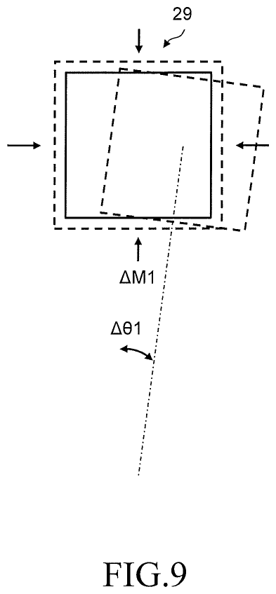

FIG. 9 illustrates an image correction method according to the first embodiment. For example, when the rotation change amount Δθ1 has been corrected at the electrostatic lens side, the image processing circuit 132 corrects the magnification change amount ΔM1. Alternatively, for example, when the magnification change amount ΔM1 has been corrected at the electrostatic lens side, the image processing circuit 132 corrects the rotation change amount Δθ1. It is preferable to perform correction for each sub-irradiation region 29 (region including margin) that is detected by one beam, for example. However, it is not limited thereto. For example, it is also preferable to perform correction for each mask die 33. When correcting the magnification change amount ΔM1, the whole correction region, such as the sub-irradiation region 29 (region including margin), may be reduced or expanded. When correcting the rotation change amount Δθ1, correction can be performed by rotating the whole correction region, such as the sub-irradiation region 29 (region including margin), in the opposite direction to the rotation change direction by the same angle as that of the rotation change. Needless to say, since this is rotation change of an image of the multiple beams 20, the rotation center of the image is not the center of the sub-irradiation region 29 which is detected by one beam. Rotation should be performed with respect to the rotation center of the rotation change of the image of the multiple beams 20. The corrected image data is output to the comparison circuit 108, together with information indicating each position from the position circuit 107.

In the reference image generating step (S205), the reference image generation circuit 112 (reference image generation unit) generates a reference image corresponding to an inspection image to be inspected. The reference image generation circuit 112 generates the reference image for each frame region, based on design data serving as a basis for forming a pattern on the substrate 101, or design pattern data defined in exposure image data of a pattern formed on the substrate 101. Preferably, for example, the mask die 33 is used as the frame region. Specifically, it operates as follows: First, design pattern data is read from the storage device 109 through the control computer 110, and each figure pattern defined in the read design pattern data is converted into image data of binary or multiple values.

Here, basics of figures defined by the design pattern data are, for example, rectangles and triangles. For example, there is stored figure data defining the shape, size, position, and the like of each pattern figure by using information, such as coordinates (x, y) of the reference position of the figure, lengths of sides of the figure, and a figure code serving as an identifier for identifying the figure type such as rectangles, triangles and the like.

When design pattern data used as the figure data is input to the reference image generation circuit 112, the data is developed into data of each figure. Then, the figure code indicating the figure shape, the figure dimensions, and the like of each figure data are interpreted. Then, the reference image generation circuit 112 develops each figure data to design pattern image data of binary or multiple values as a pattern to be arranged in squares in units of grids of predetermined quantization dimensions, and outputs the developed data. In other words, the reference image generation circuit 112 reads design data, calculates an occupancy rate occupied by a figure in the design pattern, for each square region obtained by virtually dividing the inspection region into squares in units of predetermined dimensions, and outputs n-bit occupancy rate data. For example, it is preferable to set one square as one pixel. Assuming that one pixel has a resolution of 1/2⁸(=1/256), the occupancy rate in each pixel is calculated by allocating small regions which correspond to the region of figures arranged in the pixel concerned and each of which corresponds to 1/256 resolution. Then, 8-bit occupancy rate data is output to the reference image generation circuit 112. The square region (inspection pixel) should be in accordance with the pixel of measured data.

Next, the reference image generation circuit 112 performs appropriate filter processing on design image data of a design pattern which is image data of a figure. Since optical image data as a measured image is in the state affected by filtering performed by the optical system, in other words, in an analog state continuously changing, it is possible to match/fit the design image data with the measured data by also applying a filtering process to the design image data being image data on the design side whose image intensity (gray scale level) is represented by digital values. The generated image data of a reference image is output to the comparison circuit 108.

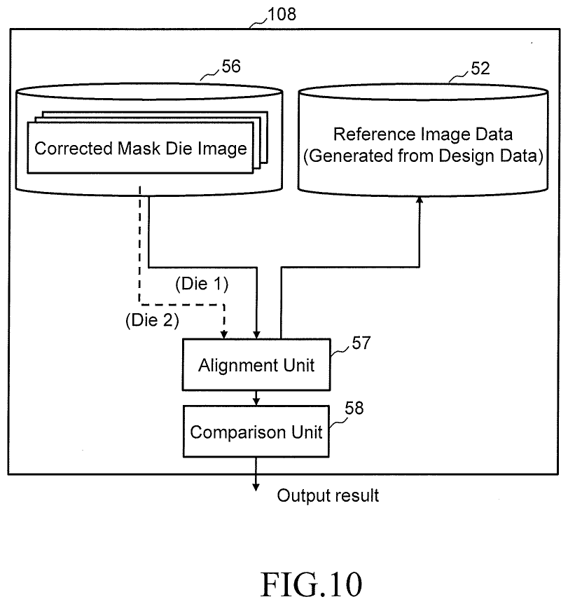

FIG. 10 shows an example of an internal configuration of a comparison circuit according to the first embodiment. In FIG. 10, storage devices 52 and 56, such as magnetic disk drives, an alignment unit 57, and a comparison unit 58 are arranged in the comparison circuit 108. Each of the “units” such as the alignment unit 57 and the comparison unit 58 includes processing circuitry. As the processing circuitry, for example, an electric circuit, computer, processor, circuit board, quantum circuit, semiconductor device, or the like can be used. Moreover, each of the “units” may use common processing circuitry (the same processing circuitry), or different processing circuitry (separate processing circuitry). Input data needed in the alignment unit 57 and the comparison unit 58, and calculated results are stored in a memory (not shown) or in the memory 118 each time.

In the comparison circuit 108, transmitted pattern image data (or secondary electron image data) is temporarily stored in the storage device 56. Moreover, transmitted reference image data is temporarily stored in the storage device 52.

In the aligning step (S206), the alignment unit 57 reads a mask die image serving as an inspection image, and a reference image corresponding to the mask die image, and provides alignment/positioning between the images based on a sub-pixel unit smaller than the pixel 36. For example, the alignment can be performed by a least-square method.

In the comparing step (S208), the comparison unit 58 compares the mask die image (inspection image) and the reference image concerned. The comparison unit 58 compares them, for each pixel 36, based on predetermined determination conditions in order to determine whether there is a defect such as a shape defect. For example, if a gray scale level difference of each pixel 36 is larger than a determination threshold Th, it is determined that there is a defect. Then, the comparison result is output, and specifically, output to the storage device 109, the monitor 117, or the memory 118, or alternatively, output from the printer 119.

Although the die-to-database inspection is described above, the die-to-die inspection may also be performed. In the case of conducting the die-to-die inspection, images of the mask dies 33, where identical patterns are formed, are compared. Accordingly, a mask die image of a partial region of the wafer die 332 serving as a die (1), and a mask die image of a corresponding region of another wafer die 332 serving as a die (2) are used. Alternatively, a mask die image of a partial region of the wafer die 332 serving as a die (1), and a mask die image of another partial region other than the above-mentioned partial region of the same wafer die 332 serving as a die (2), where identical patterns are formed, may be compared. In such a case, if one of the images of the mask dies 33 on which identical patterns are formed is used as a reference image, inspection can be performed by the same method as that of the die-to-database inspection described above.

That is, in the aligning step (S206), the alignment unit 57 reads the mask die image of the die (1) and the mask die image of the die (2), and provides alignment between the images based on a sub-pixel unit smaller than the pixel 36. For example, the alignment can be performed by a least-square method.

Then, in the comparing step (S208), the comparison unit 58 compares the mask die image of the die (1) and the mask die image of the die (2). The comparison unit 58 compares them, for each pixel 36, based on predetermined determination conditions in order to determine whether there is a defect such as a shape defect. For example, if a gray scale level difference of each pixel 36 is larger than a determination threshold Th, it is determined that there is a defect. Then, the comparison result is output, and specifically, output to a storage device, monitor, or memory (not shown), or alternatively, output from a printer.

As described above, according to the first embodiment, with respect to the three change factors, two of the focus position deviation amount ΔZ1 which is generated due to continuous movement of the stage 105, the image magnification change amount ΔM1, and the image rotation change amount Δθ1 which are generated along with the focus position deviation amount ΔZ1 are corrected by two electrostatic lenses, and the remaining one is corrected by image processing. With this configuration of the apparatus that acquires an image by focusing multiple beams on the substrate continuously moving, it is possible to make the installation space smaller and perform control more easily compared to the conventional one.

### Second Embodiment

Although the first embodiment describes a configuration that corrects the focus position deviation amount ΔZ1 and one of the image magnification change amount ΔM1 and the image rotation change amount Δθ1, which are generated along with the focus position deviation amount ΔZ1, by two electrostatic lenses, and corrects the other one of the two by image processing, it is not limited thereto. A second embodiment describes a configuration that corrects the focus position deviation amount ΔZ1 by one electrostatic lens, and the image magnification change amount ΔM1 and the image rotation change amount Δθ by image processing.

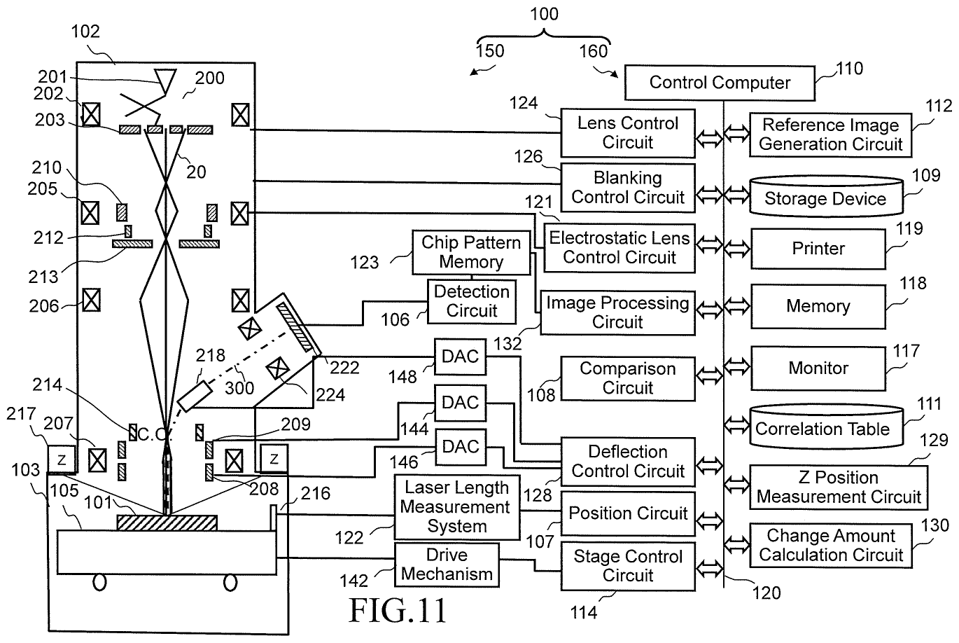

FIG. 11 shows a configuration of a pattern inspection apparatus according to the second embodiment. FIG. 11 is the same as FIG. 1 except that the electrostatic lens 211 is not arranged. Although the electrostatic lens 211 is not arranged in the case of FIG. 11, it is also preferable that the electrostatic lens 210, instead of the electrostatic lens 211, is not arranged. Similarly to the first embodiment, preferably, the electrostatic lens 210 is disposed at the position through which the multiple secondary electron beams 300 do not pass. In other words, the electrostatic lens 210 is disposed upstream of the beam separator 214 with respect to an advancing direction of the multiple beams 20.

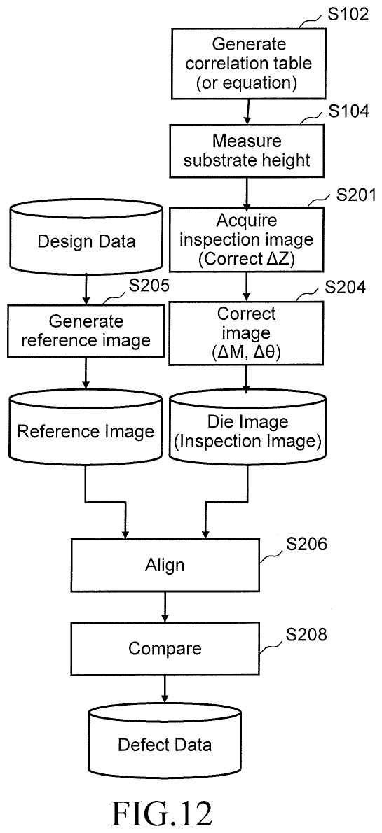

FIG. 12 is a flowchart showing main steps of an inspection method according to the second embodiment. FIG. 12 is the same as FIG. 4 except that an inspection image acquiring step (S201) is carried out instead of the inspection image acquiring step (S202), and an image correcting step (S204) is carried out instead of the image correcting step (S203). The contents of the second embodiment are the same as those of the first embodiment except for what is specifically described below.

The contents of the correlation table (or correlation equation) generating step (S102) and the substrate height measuring step (S104) are the same as those of the first embodiment.

In the inspection image acquiring step (S201), using the multiple beams 20, the image acquisition mechanism 150 acquires a secondary electron image of a pattern formed on the substrate 101. Specifically, it operates as follows:

First, the stage 105 with the substrate 101 thereon is moved in the state where the multiple beams 20 are focused on the reference position on the surface of the substrate 101 by the electromagnetic lens 207 (objective lens).

Prior to irradiating the mask die 33 concerned with the multiple beams 20, the change amount calculation circuit 130 reads the height position of the substrate 101 stored in the storage device 109, using the x and y coordinates of the irradiation positions of the multiple beams 20. The change amount calculation circuit 130 calculates a difference between the read height position and the reference position on the surface of the substrate 101 focused by the electromagnetic lens 207 (objective lens). This difference is equivalent to the focus position deviation amount ΔZ1 deviated from the reference position. Alternatively, it is also preferable to store in the storage device 109 information on the height position of the substrate 101 as a difference from the reference position, i.e., as the deviation amount ΔZ1 of the focus position deviated from the reference position.

Next, the change amount calculation circuit 130 reads the correlation table (or parameters k and k′ in the approximate expression) stored in the storage device 111, and, based on this correlation table (or approximate expression), calculates the rotation change amount Δθ1 and the magnification change amount ΔM1 depending on the focus position deviation amount ΔZ1 which is deviated from the reference position because of change of the height position of the surface of the substrate 101 changed along with movement of the stage 105. Then, according to the second embodiment, information on the focus position deviation amount ΔZ1 is output to the electrostatic lens control circuit 121. Information on each of the calculated rotation change amount Δ8l and magnification change amount ΔM1 is output to the image processing circuit 132.

The electrostatic lens control circuit 121 calculates a lens control value 1 of the electrostatic lens 210 for correcting the focus position deviation amount ΔZ1. Then, the electrostatic lens control circuit 121 applies an electric potential equivalent to the calculated lens control value 1 to the control electrode (middle electrode substrate) of the electrostatic lens 210. Since only one of the three change factors, namely the focus position deviation amount ΔZ1, the rotation change amount Δθ1, and the magnification change amount ΔM1, is corrected, it is easier to perform controlling than performing correction controlling of all the three change factors. Therefore, enlargement of the control system can be inhibited. Thus, as long as the height position of the substrate 101, further the amount deviation ΔZ1 of the focus position, can be acquired using the correlation table (or approximate expression), the rotation change amount Δθ1 and the magnification change amount ΔM1 can be obtained, thereby simplifying the control system.

The image acquisition mechanism 150 irradiates the substrate 101 with the multiple beams 20 while continuously moving the stage 105. By this, the electrostatic lens 210 (first electrostatic lens) dynamically corrects deviation of the focus position from the reference position on the surface of the substrate 101, which is deviated along with movement of the stage 105. Similarly to the first embodiment, each beam of the multiple beams 20 is associated with any one of the sub-irradiation regions 29 which are different from each other. At the time of each shot, each beam irradiates the same position in the associated sub-irradiation region 29. By repeating this operation, one beam irradiates all the pixels in order in one sub-irradiation region 29. In addition, since the image rotation change amount Δθ1 and the image magnification change amount ΔM1 remain in the data to be obtained, it is preferable to add a margin to the sub-irradiation region 29 to be scanned with each beam.

The multiple secondary electron beams 300 including reflected electrons, each corresponding to each of the multiple beams 20, are emitted from the substrate 101 because desired positions on the substrate 101 are irradiated with the multiple beams 20 having been corrected by the electrostatic lens 210. The multiple secondary electron beams 300 emitted from the substrate 101 travel to the beam separator 214, and are bent obliquely upward. Then, the trajectory of the multiple secondary electron beams 300 having been bent obliquely upward is bent by the deflector 218, and projected on the multi-detector 222. As described above, the multi-detector 222 detects the multiple secondary electron beams 300, including reflected electrons, emitted because the substrate 101 surface is irradiated with the multiple beams 20.

Thus, the whole of the multiple beams 20 scans the mask die 33 as the irradiation region 34, and that is, each beam individually scans one corresponding sub-irradiation region 29. Similarly to the first embodiment, after scanning one mask die 33, the irradiation region 34 is moved to a next adjacent mask die 33 so as to be scanned. In conjunction with this operation, the electrostatic lens 210 dynamically corrects the focus position deviation amount ΔZ1 which is deviated from the reference position of the multiple beams 20. This operation is repeated to proceed scanning of each chip 332. Due to shots of the multiple beams 20, secondary electrons are emitted from the irradiated positions at each shot time, and detected by the multi-detector 222.

Detected data (measured image: secondary electron image: image to be inspected) on a secondary electron from each measurement pixel 36 detected by the multi-detector 222 is output to the detection circuit 106 in order of measurement. In the detection circuit 106, the detected data in analog form is converted into digital data by an A-D converter (not shown), and stored in the chip pattern memory 123. Thus, the image acquisition mechanism 150 acquires a measured image of a pattern formed on the substrate 101. Then, for example, when the detected data for one chip 332 has been accumulated, the accumulated data is transmitted as chip pattern data to the image processing circuit 132, together with information data on each position from the position circuit 107.

In the image correcting step (S204), using the correlation table (or approximate expression), the image processing circuit 132 (image processing unit) corrects both of the rotation change amount Δθ1 and the magnification change amount ΔM1 which are depending on the deviation amount ΔZ1 of the focus position, with respect to a secondary electron image based on a detection signal of detected multiple secondary electron beams. The method for correcting an image is the same as that described with reference to FIG. 9. It is preferable to perform correction for each sub-irradiation region 29 (region including margin) that is detected by one beam, for example. However, it is not limited thereto. For example, it is also preferable to perform correction for each mask die 33. When correcting the magnification change amount ΔM1, the whole correction region, such as the sub-irradiation region 29 (region including margin), may be reduced or expanded. When correcting the rotation change amount Δθ1, correction can be performed by rotating the whole correction region, such as the sub-irradiation region 29 (region including margin), in the opposite direction to the rotation change direction by the same angle as that of the rotation change. The corrected image data is output to the comparison circuit 108, together with information indicating each position from the position circuit 107.

The contents of each step after the reference image generating step (S205) are the same as those of the first embodiment.

As described above, according to the second embodiment, with respect to the three change factors, namely the focus position deviation amount ΔZ1 which is generated due to continuous movement of the stage 105, and the image magnification change amount ΔM1 and the image rotation change amount Δθ1 which are generated along with the focus position deviation amount ΔZ1, the focus position deviation amount ΔZ1 is corrected by one electrostatic lens, and the other two are corrected by image processing. With this configuration of the apparatus that acquires an image by focusing multiple beams on the substrate continuously moving, it is possible to make the installation space smaller and perform control more easily compared to the conventional one.

In the above description, each “ . . . circuit” includes processing circuitry. As the processing circuitry, for example, an electric circuit, computer, processor, circuit board, quantum circuit, semiconductor device, or the like can be used. Each “ . . . circuit” may use common processing circuitry (the same processing circuitry), or different processing circuitry (separate processing circuitry). A program for causing a processor to execute processing or the like may be stored in a recording medium, such as a magnetic disk drive, magnetic tape drive, FD, ROM (Read Only Memory), etc. For example, the position circuit 107, the comparison circuit 108, the reference image generation circuit 112, the stage control circuit 114, the electrostatic lens control circuit 121, the lens control circuit 124, the blanking control circuit 126, the deflection control circuit 128, the Z position measurement circuit 129, the change amount calculation circuit 130, and the image processing circuit 132 may be configured by at least one processing circuit described above.

Embodiments have been explained referring to specific examples described above. However, the present invention is not limited to these specific examples. Although FIG. 1 describes the case where the multiple primary electron beams 20 are formed by the shaping aperture array substrate 203 irradiated with one beam from one irradiation source, namely, the electron gun 201, it is not limited thereto. The multiple primary electron beams 20 may be formed by individual irradiation with primary electron beams from a plurality of irradiation sources.

While the apparatus configuration, control method, and the like not directly necessary for explaining the present invention are not described, some or all of them can be appropriately selected and used on a case-by-case basis when needed.

In addition, any other multi-electron beam image acquisition apparatus, multi-electron beam image acquisition method, and multiple electron beam inspection apparatus that include elements of the present invention and that can be appropriately modified by those skilled in the art are included within the scope of the present invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A multi-electron beam image acquisition apparatus comprising:
a stage which is configured to mount thereon a substrate to be irradiated with multiple electron beams, and is movable continuously;
an objective lens configured to focus the multiple electron beams on a reference position on a surface of the substrate;
a storage device configured to store one of a table and a parameter in an approximate expression, where a rotation change amount and a magnification change amount of an image of the multiple electron beams, generated due to correcting a focus position deviation amount deviated from the reference position because of change of a height position of the surface of the substrate, are defined depending on the focus position deviation amount;
a first electrostatic lens and a second electrostatic lens configured to, using the one of the table and the approximate expression, dynamically correct the focus position deviation amount deviated from the reference position because of the change of the height position of the surface of the substrate changed along with movement of the stage, and correct one of the rotation change amount and the magnification change amount depending on the focus position deviation amount by interaction;
a detector configured to detect multiple secondary electron beams emitted from the substrate by irradiation on the substrate with the multiple electron beams having been corrected by the first electrostatic lens and the second electrostatic lens; and
an image processing circuit configured to, using the one of the table and the approximate expression, correct another of the rotation change amount and the magnification change amount depending on the focus position deviation amount, with respect to a secondary electron image based on a detection signal of the multiple secondary electron beams having been detected.

2. A multi-electron beam image acquisition apparatus comprising:
a stage which is configured to mount thereon a substrate to be irradiated with multiple electron beams, and is movable continuously;
an objective lens configured to focus the multiple electron beams on a reference position on a surface of the substrate;
a first electrostatic lens configured to dynamically correct a focus position deviation amount, deviated from the reference position, generated along with movement of the stage;
a storage device configured to store one of a table and a parameter in an approximate expression, where a rotation change amount and a magnification change amount of an image of the multiple electron beams, generated due to dynamically correcting the focus position deviation amount by the first electrostatic lens, are defined depending on the focus position deviation amount;
a detector configured to detect multiple secondary electron beams emitted from the substrate by irradiation on the substrate with the multiple electron beams having been corrected by the first electrostatic lens; and
an image processing circuit configured to, using the one of the table and the approximate expression, correct both of the rotation change amount and the magnification change amount depending on the focus position deviation amount, with respect to a secondary electron image based on a detection signal of the multiple secondary electron beams having been detected.

3. The apparatus according to claim 1, wherein the first electrostatic lens and the second electrostatic lens are disposed at positions through which the multiple secondary electron beams do not pass.

4. The apparatus according to claim 2, wherein the first electrostatic lens is disposed at a position through which the multiple secondary electron beams do not pass.

5. The apparatus according to claim 1, further comprising:
a beam separator configured to separate the multiple electron beams and the multiple secondary electron beams, wherein
the first electrostatic lens and the second electrostatic lens are disposed upstream of the beam separator with respect to an advancing direction of the multiple electron beams.

6. The apparatus according to claim 2, further comprising:
a beam separator configured to separate the multiple electron beams and the multiple secondary electron beams, wherein
the first electrostatic lens is disposed upstream of the beam separator with respect to an advancing direction of the multiple electron beams.

7. The apparatus according to claim 1, wherein the rotation change amount is a rotation change amount of an image on the surface of the substrate.

8. The apparatus according to claim 1, wherein the magnification change amount is a magnification change amount of an image on the surface of the substrate.

9. A multi-electron beam image acquisition method comprising:
moving a stage with thereon a substrate in a state where multiple electron beams are focused on a reference position on a surface of the substrate by an objective lens;
reading, from a storage device, one of a table and an approximate expression in which a rotation change amount and a magnification change amount of an image of the multiple electron beams, generated due to correcting a focus position deviation amount deviated from the reference position because of change of a height position of the surface of the substrate, are defined depending on the focus position deviation amount, and dynamically correcting, with a first electrostatic lens and a second electrostatic lens, the focus position deviation amount deviated from the reference position because of the change of the height position of the surface of the substrate changed along with movement of the stage, and one of the rotation change amount and the magnification change amount depending on the focus position deviation amount by interaction, using the one of the table and the approximate expression;
detecting multiple secondary electron beams emitted from the substrate by irradiation on the substrate with the multiple electron beams having been corrected by the first electrostatic lens and the second electrostatic lens; and
correcting, using the one of the table and the approximate expression, another of the rotation change amount and the magnification change amount depending on the focus position deviation amount, with respect to a secondary electron image based on a detection signal of the multiple secondary electron beams having been detected, and outputting a corrected secondary electron image.

10. A multi-electron beam image acquisition method comprising:
moving a stage with thereon a substrate in a state where multiple electron beams are focused on a reference position on a surface of the substrate by an objective lens;
correcting dynamically, by a first electrostatic lens, a focus position deviation amount deviated from the reference position on the surface of the substrate and generated along with movement of the stage;
detecting multiple secondary electron beams emitted from the substrate by irradiation on the substrate with the multiple electron beams having been corrected by the first electrostatic lens; and
reading, from a storage device which stores one of a table and a parameter in an approximate expression, the one of the table and the approximate expression in which a rotation change amount and a magnification change amount of an image of the multiple electron beams, generated due to dynamically correcting the focus position deviation amount by the first electrostatic lens, are defined depending on the focus position deviation amount, and correcting, using the one of the table and the approximate expression, both of the rotation change amount and the magnification change amount depending on the focus position deviation amount, with respect to a secondary electron image based on a detection signal of the multiple secondary electron beams having been detected, so as to output a corrected secondary electron image.
